(19) United States
(12) Patent Application Publication
(10) Pub. No.: US 2008/0088020 A1
(43) Pub. Date: Apr. 17, 2008

(54) SEMICONDUCTOR DEVICE AND MANUFACTURING METHOD OF THE SAME

(75) Inventors: Kenichi MIYAJIMA, Toyama (JP); Keiichi MURAYAMA, Toyama (JP); Hirotaka MIYAMOTO, Toyama (JP); Akiyoshi TAMURA, Osaka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/774,821

(22) Filed: Jul. 9, 2007

(30) Foreign Application Priority Data
Oct. 16, 2006 (JP) 2006-281679

(51) Int. Cl. H01L 23/48; H01L 21/44

(52) U.S. Cl. 257/750; 438/652; 257/E23.01; 257/E21.476

(57) ABSTRACT

Provided is a semiconductor device and a manufacturing method of the same which improve adhesion of a semiconductor substrate to a metal wire, the semiconductor substrate having a via hole formed from a bottom surface of the semiconductor substrate up to the metal wire on a top surface of the semiconductor substrate, and the metal wire being positioned on the top surface of the semiconductor substrate where there is an opening formed since the via hole is formed. The semiconductor device includes: a metal layer formed on a semiconductor substrate; an alloy reaction layer formed below the metal layer as a result of an alloy reaction between the semiconductor substrate and the metal layer; and a via hole formed from a bottom surface side of the semiconductor substrate up to the metal layer or up to the alloy reaction layer.

### BACKGROUND OF THE INVENTION

(1) Field of the Invention

The present invention relates to a semiconductor device having a via hole and a manufacturing method of the semiconductor device, and particularly relates to a semiconductor device having a via hole which is formed from a bottom surface of a semiconductor substrate up to metal on a top surface of the semiconductor substrate and a manufacturing method of the semiconductor device.

(2) Description of the Prior Art

Among high frequency analog elements, semiconductor devices used for power amplifiers (hereinafter referred to as “PA”) have conventionally been connected to a mounting substrate to establish a ground connection through a via hole formed from a bottom surface of each semiconductor device up to a wire on the semiconductor substrate. Compared to a method of connecting the semiconductor devices to the mounting substrate for a ground connection by wire bonding, the above described method of connecting the semiconductor devices to the mounting substrate for a ground connection through the via hole allows an excess inductance of the wire to be eliminated, and thus a high frequency characteristic is improved. In addition, since the via hole serves as a passage of heat allowing heat to dissipate towards the mounting substrate, a heat dissipation is also improved.

With reference to a drawing, the following describes a device structure of a general semiconductor device, such as a PA, having a via hole formed on a bottom surface of a substrate of the semiconductor device (See, for example, Patent Reference 1: Japanese Unexamined Patent Application Publication No. 2005-72378).

FIG. 1 is a cross section showing a structure of a field-effect transistor (hereinafter referred to as “FET”) having a via hole formed on a bottom surface of a semiconductor substrate. As shown in FIG. 1, the FET has a gate electrode 702, a drain electrode 703, and a source electrode 704, each of which is formed on a semi-insulating GaAs substrate 701, and the source electrode 704 and a wire 705 formed on the GaAs substrate 701 are connected. Further, a via hole 706 (hereinafter referred to as “bottom surface via hole”) is formed from the bottom surface of the GaAs substrate 701 up to the wire 705 formed on a top surface of the GaAs substrate 701, and a bottom surface electrode 707 is formed on a sidewall of the bottom surface via hole 706. Furthermore, the bottom surface electrode 707 is also formed on an opening, in the bottom surface via hole 706, of the GaAs substrate 701 located below the wire 705, and also on the bottom surface of the GaAs substrate 701. As a result, the bottom surface electrode 707 is connected to the wire 705.

Here, the wire 705 serves as an etching stopper when the bottom surface via hole 706 is formed, that is, when an etching process is performed.

Incidentally, with the method of manufacturing a conventional semiconductor device such as the PA device shown in FIG. 1, the wire 705 formed on the GaAs substrate 701 is made of, for example, Ti/Pt/Au (a laminated structure having Ti, Pt and Au, where Ti is the bottom layer and Au is the top layer), and is simply placed on the GaAs substrate. Here, the expression of A/B/C indicates that the layers are laminated from the bottom, in the order of A, B and C. Further, the bottom surface via hole 706 is formed in such manner that it is formed from the bottom surface of the GaAs substrate up to the bottom surface of the wire 705. The contact area of the wire 705 with the GaAs substrate 701 is reduced by an opening of the top surface of the GaAs substrate 701 which is open since the bottom surface via hole 706 is formed. As a result, adhesion of the wire 705 to the GaAs substrate 701 deteriorates, and thus, there are cases where the wire 705 comes off from the GaAs substrate 701 due to a manufacturing stress, for example, which is known as metal coming-off.

### SUMMARY OF THE INVENTION

In view of the above described problem, an object of the present invention is to provide: a structure of a semiconductor device and a manufacturing method of the same which improve adhesion of a semiconductor substrate to a metal wire and reduce occurrence of metal coming-off, the semiconductor substrate having a via hole formed from a bottom surface of the semiconductor substrate up to the metal wire on the semiconductor substrate, and the metal wire being positioned on a top surface of the semiconductor substrate where there is an opening formed since the via hole is formed.

In order to achieve the above object, the semiconductor according to the present invention includes: a metal layer formed on a semiconductor substrate; an alloy reaction layer formed below the metal layer as a result of an alloy reaction between the semiconductor substrate and the metal layer; and a via hole formed from a bottom surface side of the semiconductor substrate up to the metal layer or up to the alloy reaction layer. Here, the metal layer may be made of two or more laminated metal layers, and the closest of the laminated metal layers to the semiconductor substrate may be made of AuGe. Also, the closest of the laminated metal layers to the semiconductor substrate may be made of Pt.

With the above described structure, the adhesion of the metal wire to the semiconductor layer improves as a result of having the alloy reaction layer. That is to say, even though the contact area of the metal wire with the semiconductor substrate is reduced by the opening of the top surface of the semiconductor substrate which is open since the via hole is formed, the adhesion of the metal wire to the semiconductor layer improves since the alloy reaction layer is formed, and thus, the opening does not cause deterioration in the adhesion. Therefore, it is possible to reduce the occurrence of the phenomenon that the metal wire comes off from the semiconductor substrate due to a manufacturing stress, for example, that is, it is possible to reduce the occurrence of the metal coming-off.

Further, the semiconductor device may further include a semiconductor element, and the metal layer and an electrode of the semiconductor element may be made of an identical metal material.

With this structure, since the metal wire and the electrode of the semiconductor element can simultaneously be formed and the number of manufacturing processes can be reduced, it is possible to reduce the manufacturing cost.

The manufacturing method of the semiconductor device according to the present invention includes: laminating a metal layer on a semiconductor substrate; forming an alloy reaction layer by causing an alloy reaction between the metal layer and the semiconductor substrate; and forming a via hole from a bottom surface side of the semiconductor substrate up to the metal layer or up to the alloy reaction layer.

With this, heat treatment causes an alloy reaction between the metal wire and the semiconductor substrate, and the alloy reaction layer is formed, and thus, the alloy reaction layer allows an improvement in the adhesion of the metal wire to the semiconductor substrate. That is to say, even though the contact area of the metal wire with the semiconductor substrate is reduced by the opening of the top surface of the semiconductor substrate which is open since the via hole is formed, the adhesion of the metal wire to the semiconductor layer improves because the alloy reaction layer is formed, and thus, the opening does not cause deterioration in the adhesion. Therefore, it is possible to reduce the occurrence of the phenomenon that the metal wire comes off from the semiconductor substrate due to a manufacturing stress, for example, that is, it is possible to reduce the occurrence of the metal coming-off.

Further, the laminating of the metal layer may include simultaneously forming the metal layer and an electrode of a semiconductor element formed on the semiconductor substrate.

With this, the metal wire and the electrode of the semiconductor element can simultaneously be formed, and thus, the number of manufacturing processes can be reduced. In other words, the processing cost can be reduced.

According to the structure of the semiconductor device and the manufacturing method of the same of the present invention, it is possible to realize a structure of a semiconductor device and a manufacturing method of the same that improve adhesion of a semiconductor substrate to a metal wire and reduce occurrence of the metal coming-off, the semiconductor substrate having a via hole formed from a bottom surface of the semiconductor substrate up to the metal wire on a top surface of the semiconductor substrate, and the metal wire being positioned on the top surface of the semiconductor substrate where there is an opening formed since a via hole is formed.

### Further Information About Technical Background to this Application

The disclosure of Japanese Patent Application No. 2006-281679 filed on Oct. 16, 2006 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings which illustrate a specific embodiment of the invention. In the Drawings:

FIG. 1 is a cross section showing a structure of a conventional semiconductor device.

FIG. 2 is a cross section showing a structure of a semiconductor device according to an embodiment of the present invention.

FIG. 3 is a cross section schematically showing a structure of a metal wire according to the embodiment of the present invention.

FIGS. 4A to 4J are cross sections showing a structure of the semiconductor device according to the embodiment of the present invention.

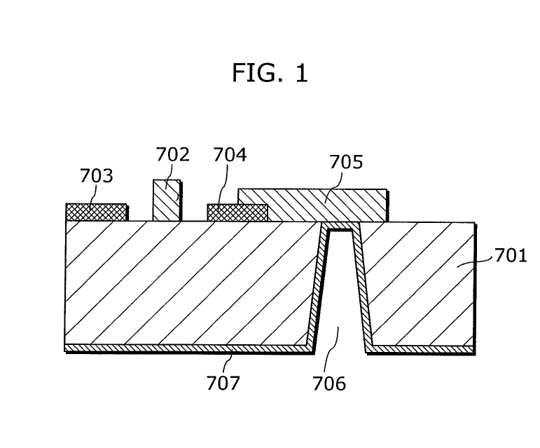

### DESCRIPTION OF A PREFERRED EMBODIMENT

With reference to the drawings, the following describes a semiconductor device and a manufacturing method of the same according to an embodiment of the present invention.

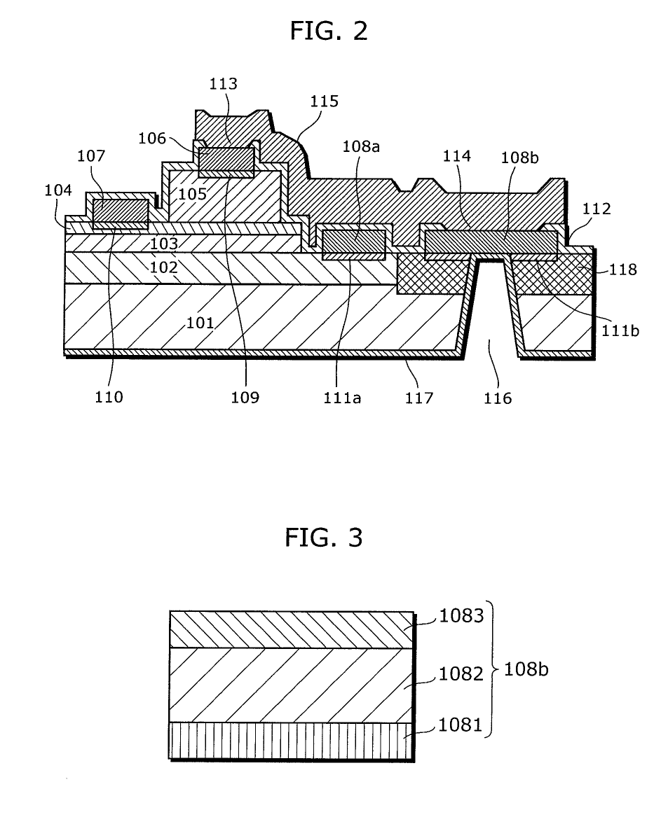

FIG. 2 is a cross section of the semiconductor device according to the present embodiment.

As shown in FIG. 2, this semiconductor device 100 has: an n-type GaAs subcollector layer 102 to which an n-type impurity is doped in high concentration and which is formed on a semiconductor substrate 101 that is made of semi-insulating GaAs; an n-type GaAs collector layer 103; a p-type GaAs base layer 104; and an n-type semiconductor emitter layer 105 which has a laminated structure that includes InGaP, the n-type GaAs collector layer 103, the p-type GaAs base layer 104, and the n-type semiconductor emitter layer 105 being sequentially laminated on the n-type GaAs subcollector layer 102.

On the n-type semiconductor emitter layer 105, an emitter electrode 106 made of Pt/Ti/Pt/Au is formed. On the p-type GaAs base layer 104, a base electrode 107 made of Pt/Ti/Pt/Au is formed. On the n-type GaAs subcollector layer 102, a collector electrode 108a made of AuGe/Ni/Au, and a metal wire 108b are formed. Here, the metal wire 108b is exemplified in FIG. 3. FIG. 3 is a cross section schematically showing a laminated structure of the metal wire 108b. The metal wire 108b is made of two or more laminated metal layers, and here, it is made of three laminated metal layers. More specifically, a bottom layer 1081 of the laminated metal layers of the metal wire 108b is made of AuGe, a middle layer 1082 of the laminated metal layers of the metal wire 108b is made of Ni, and a top layer 1083 of the laminated metal layers of the metal wire 108b is made of Au. This is the same for the collector electrode 108a.

Further, below the emitter electrode 106, the base electrode 107, the collector electrode 108a, and the metal wire 108b, alloy reaction layers 109, 110, 111a and 111b are respectively formed as a result of alloy reactions, caused by heat treatment, between these electrodes and the metal wire 108b, and the semiconductor substrates 105, 104 and 102 which are respectively positioned below these electrodes and the metal wire 108b.

Furthermore, in the n-type GaAs subcollector layer 102 positioned below the metal wire 108b, an element separating region 118 is formed so as to electrically separate the metal wire 108b and a semiconductor element formed on the semiconductor substrate 101.

In addition, an insulator film 112 is placed so as to cover entire exposed parts of the semiconductor top surface, that is, to cover exposed parts of the n-type GaAs subcollector layer 102, the n-type GaAs collector layer 103, the p-type GaAs base layer 104, the n-type semiconductor emitter layer 105, the emitter electrode 106, the base electrode 107, the collector electrode 108a, the metal wire 108b, and the element separating region 118. In doing so, the insulator film 112 just above the emitter electrode 106 and the metal wire 108b is open (hereinafter referred to as contact holes 113 and 114). Further, an emitter electrode top part wire 115 is formed so as to cover the contact holes 113 and 114, that is, to cover from the top part of the emitter electrode 106 up to the top part of the metal wire 108b. Via the emitter electrode top part wire 115, the emitter electrode 106 and the metal wire 108b are connected.

Furthermore, a via hole 116 (hereinafter referred to as “bottom surface via hole”) is formed from the bottom surface of the semiconductor substrate 101 made of semi-insulating GaAs up to the metal wire 108b formed on the semiconductor substrate 101 made of semi-insulating GaAs. On a sidewall of the bottom surface via hole 116, a bottom surface electrode 117 made of Ti/Au is formed. Further, the bottom surface electrode 117 is also formed on the edge of the via hole on the metal wire 108b side, and also formed on the bottom surface of the semiconductor substrate 101 made of semi-insulating GaAs. Thus, the bottom surface electrode 117 is connected to the metal wire 108b.

With the semiconductor device 100 having the above described structure, the metal wire 108b made of AuGe/Ni/Au forms an alloy reaction layer 111b as a result of an alloy reaction, caused by heat treatment, with the element separating region 118, that is, the electrically separated n-type GaAs semiconductor layer. In doing so, the alloy reaction layer 111b forms an ohmic contact with the semiconductor layer of the element separating region 118 and with the metal wire 108b. In other words, by forming the ohmic contact, it is possible to prevent formation of a parasitic diode. In the same manner, the alloy reaction layers 109, 110, and 111a which are respectively formed below the emitter electrode 106, the base electrode 107, and the collector electrode 108a respectively form an ohmic contact with the semiconductor substrates 105, 104, and 102.

Also, the metal wire 108b made of AuGe/Ni/Au serves as an etching stopper when the bottom surface via hole 116 is formed, that is, when an etching process is performed.

Here, the metal wire 108b may include Pt, and may thus be made of Pt/Ti/Pt/Au. In such a case, the metal wire 108b may simultaneously be formed with the emitter electrode 106 and the base electrode 107. With the above described structure, the adhesion of the metal wire 108b to the element separating region 118, that is, the semiconductor layer made of n-type GaAs, improves as a result of having the alloying reaction layer 111b. That is to say, even though the contact area of the metal wire 108b with the element separating region 118 is reduced by the opening of the GaAs substrate top surface which is open since the bottom surface via hole 116 is formed, the adhesion of the metal wire 108b to the semiconductor layer made of n-type GaAs improves since the alloy reaction layer 111b is formed, and thus, the opening does not cause deterioration in the adhesion. Therefore, it is possible to reduce the occurrence of the phenomenon that the metal wire 108b comes off from the GaAs substrate due to a manufacturing stress, for example, that is, it is possible to reduce the occurrence of the metal coming-off. Furthermore, since the alloy reaction layer 111b forms an ohmic contact with the semiconductor layer of the element separating region 118 and with the metal wire 108b, forming the alloy reaction layer 111b does not impair electric voltage characteristics of the metal wire 108b and of the semiconductor layer made of n-type GaAs.

Here, although a heterojunction bipolar transistor (hereinafter referred to as “HBT”) has been described above as an example of the semiconductor device of the present embodiment, the present invention is not limited to this and a field effect transistor may be used instead, for example.

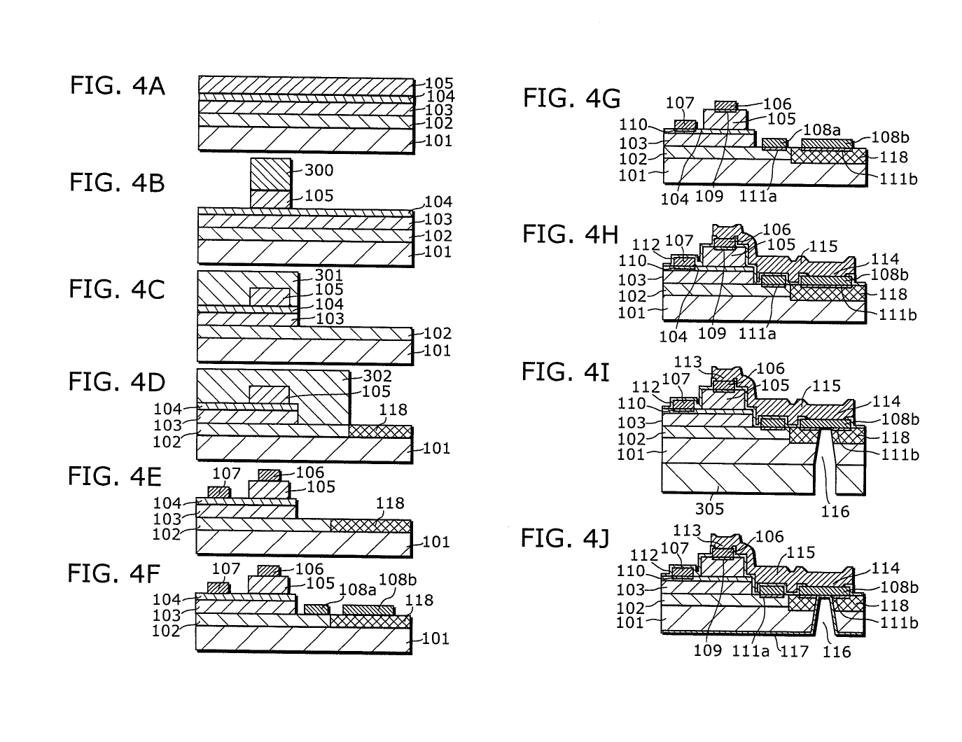

Next, with reference to FIGS. 4A to 4J, the following describes a manufacturing method of the semiconductor device 100 having the above described structure. Note that the same reference numbers are given to elements which are the same as those in FIG. 2, and their detailed description is omitted here.

FIGS. 4A to 4J are cross sections showing an HBT which is a semiconductor device. Although the HBT is described here as an example of the semiconductor device 100 according to the present embodiment, the present invention is not limited to this.

First, as shown in FIG. 4A, by crystal growth for which a method such as a Molecular Beam Epitaxy (MBE) method or a Metal Organic Chemical Vapor Deposition (MOCVD) method is used, the n-type GaAs subcollector layer 102, the n-type GaAs collector layer 103, the p-type GaAs base layer 104, and the n-type semiconductor emitter layer 105 having a laminated structure that includes InGaP are sequentially laminated on the semiconductor substrate 101 made of semi-insulating GaAs.

Next, as shown in FIG. 4B, a pattern of the n-type semiconductor emitter layer 105 having the laminated structure that includes InGaP is formed using a photoresist 300, and by dry etching or wet etching, the n-type semiconductor emitter layer 105 having a mesa shape and the laminated structure that includes InGaP is formed.

Next, as shown in FIG. 4C, by a photoresist 301, the n-type semiconductor emitter layer 105 is protected, and patterns of the n-type GaAs collector layer 103 and the p-type GaAs base layer 104 are formed. Then, by dry etching or wet etching, the p-type GaAs base layer 104 having a mesa shape and the n-type GaAs collector layer 103 having a mesa shape are formed.

Next, as shown in FIG. 4D, a pattern for forming the element separating region 118 is formed using a photoresist 302, and the element separating region 118 is formed by implanting He ion to the n-type GaAs subcollector layer 102.

Next, as shown in FIG. 4E, after a pattern of a photoresist for forming the emitter electrode 106 and the base electrode 107 is formed, the emitter electrode 106 and the base electrode 107 made of Pt/Ti/Pt/Au are simultaneously formed by vapor deposition of metal onto the n-type semiconductor emitter layer 105 and onto the p-type GaAs base layer 104 and then lifting off the metal.

Next, as shown in FIG. 4F, by forming a pattern of a photoresist for forming the collector electrode 108a and the metal wire 108b and by vapor deposition of metal onto the n-type GaAs subcollector layer 102 and lifting off the metal, the collector electrode 108a and the metal wire 108b made of AuGe/Ni/Au are simultaneously formed. The collector electrode 108a and the metal wire 108b include laminated metal layers as shown in FIG. 3.

Subsequently, as shown in FIG. 4G, heat treatment simultaneously: inactivates the element separating region 118; and causes alloy reactions between the emitter electrode 106, the base electrode 107, the collector electrode 108a and the metal wire 108b, and the semiconductor layers below the mentioned electrodes and the wire. As a result, the element separating region 118 is electrically separated, and the alloy reaction layers 109, 110, 111a, and 111b are respectively formed below the respective electrodes and the wire, that is, below the emitter electrode 106, the base electrode 107, the collector electrode 108a, and the metal wire 108b.

Next, as shown in FIG. 4H, the insulator film 112 made of SiN is deposited in such a manner to cover the entire exposed top surface of the semiconductor shown in FIG. 4G, that is, to cover the entire exposed parts of the n-type GaAs subcollector layer 102, the n-type GaAs collector layer 103, the p-type GaAs base layer 104, the n-type semiconductor emitter layer 105, the emitter electrode 106, the base electrode 107, the collector electrode 108a, the metal wire 108b, and the element separating region 118, and after that, the emitter electrode 106 and the metal wire 108b are opened so as to form the contact holes 113 and 114. Then, by vapor deposition of metal onto the insulator film 112 made of SiN and lifting off the metal, the emitter electrode top part wire 115 is formed so as to connect with the emitter electrode 106 and with the metal wire 108b via the contact holes 113 and 114.

Next, as shown in FIG. 4I, a pattern of a photoresist 305 for forming the bottom surface via hole 116 on the bottom surface side of the semiconductor substrate 101 made of semi-insulating GaAs is formed, and the bottom surface via hole 116 is formed by dry etching. The bottom surface via hole 116 penetrates the semiconductor substrate 101 made of semi-insulating GaAs, the element separating region 118, and the alloying reaction layer 111b, and reaches the metal wire 108b. The metal wire 108b made of AuGe/Ni/Au functions as an etching stopper, and thus the metal wire 108b is not etched, but only the semiconductor substrate is etched. As described, since the metal wire 108b serves as the etching stopper, it is possible to form, by etching, the bottom surface via hole 116 having very high workability.

Next, as shown in FIG. 4J, metal is deposited on the bottom surface side of the semiconductor substrate 101 made of semi-insulating GaAs by means of vapor deposition, sputtering or plating on the bottom surface of the semiconductor substrate 101, so as to form the bottom surface electrode 117. In doing so, the bottom surface electrode 117 is deposited on: the entire bottom surface of the semiconductor substrate 101 made of semi-insulating GaAs; the entire sidewall of the bottom surface via hole 116; and a part of the metal wire 108b which is exposed due to the formation of the bottom surface via hole 116.

Note that the above description is about the case of simultaneously forming the collector electrode 108a and the metal wire 108b which functions as the etching stopper when the bottom surface via hole 116 is formed, but it is needless to say that the present invention can be also applied to a case of simultaneously forming the metal wire 108b and the emitter electrode 106, or the metal wire 108b and the base electrode 107.

Also, although the above description is about the HBT for which the emitter layer having the laminated structure of the semiconductor that includes InGaP is used, it is needless to say that the present invention can be also applied to an HBT for which an emitter layer having a laminated structure of a semiconductor that includes AlGaAs is used. In addition, although the above description has been provided using the HBT as a PA device, it is needless to say that the present invention can be also applied to an FET.

As described above, according to the semiconductor device and the manufacturing method of the present embodiment, it is possible to simultaneously form the metal wire 108b and the electrode of the semiconductor device 100, and thus the number of the manufacturing processes can be reduced. Also, by using the metal made of AuGe/Ni/Au for the metal wire 108b, for example, the metal wire 108b can function as the etching stopper in the etching process for forming the bottom surface via hole 116, and the bottom surface via hole 116 can be formed with high workability, Further, by using the metal made of AuGe/Ni/Au for the metal wire 108b, for example, it is possible to form the alloying reaction layer 111b as a result of an alloy reaction, caused by heat treatment, with the element separating region 118, that is, the semiconductor layer which is electrically separated and is made of n-type GaAs. Therefore, the adhesion of the metal wire 108b to the element separating region 118, that is, the semiconductor layer made of n-type GaAs, improves as a result of having the alloying reaction layer 111b. Consequently, it is possible to reduce the occurrence of the phenomenon that the metal wire 108b comes off from the GaAs substrate due to a manufacturing stress, for example, that is, it is possible to reduce the occurrence of the metal coming-off. Also, since the alloy reaction layer 111b forms an ohmic contact with the semiconductor layer of the element separating region 118 and with the metal wire 108b, having the alloy reaction layer 111b improves the adhesion of the metal wire 108b to the semiconductor layer without impairing electric characteristics of the metal wire 108b and the semiconductor layer.

The present invention is applicable to a semiconductor device having a bottom surface via hole and a manufacturing method of the semiconductor device, and especially to FETs, HBTs, and PA devices having a bottom surface via hole.

Although only an exemplary embodiment of this invention has been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. A semiconductor device comprising:
a metal layer formed on a semiconductor substrate;
an alloy reaction layer formed below said metal layer as a result of an alloy reaction between the semiconductor substrate and said metal layer; and
a via hole formed from a bottom surface side of the semiconductor substrate up to said metal layer or up to said alloy reaction layer.

2. The semiconductor device according to claim 1,
wherein said metal layer is made of two or more laminated metal layers, and the closest of said laminated metal layers to the semiconductor substrate is made of AuGe.

3. The semiconductor device according to claim 1,
wherein said metal layer is made of two or more laminated metal layers, and the closest of said laminated metal layers to the semiconductor substrate is made of Pt.

4. The semiconductor device according to claim 1, further comprising
a semiconductor element,
wherein said metal layer and an electrode of said semiconductor element are made of an identical metal material.

5. The semiconductor device according to claim 4,
wherein said semiconductor element is a heterojunction bipolar transistor.

6. The semiconductor device according to claim 4,
wherein said semiconductor element is a field effect transistor.

7. A manufacturing method of a semiconductor device, said method comprising:
laminating a metal layer on a semiconductor substrate;
forming an alloy reaction layer by causing an alloy reaction between the metal layer and the semiconductor substrate; and
forming a via hole from a bottom surface side of the semiconductor substrate up to the metal layer or up to the alloy reaction layer.

8. The manufacturing method of the semiconductor device according to claim 7,
wherein said laminating of the metal layer includes simultaneously forming the metal layer and an electrode of a semiconductor element formed on the semiconductor substrate.
